(19) United States
(12) Patent Application Publication
(10) Pub. No.: US 2025/0119147 A1
(43) Pub. Date: Apr. 10, 2025

(54) CIRCUIT SYSTEM

(71) Applicant: ROHM CO., LTD., Kyoto-shi (JP)

(72) Inventors: Kohta MINAMOTO, Kyoto-shi (JP); Kohei TANIMITSU, Kyoto-shi (JP)

(21) Appl. No.: 18/904,537

(22) Filed: Oct. 2, 2024

(30) Foreign Application Priority Data
Oct. 4, 2023 (JP) 2023-173210

(51) Int. Cl. H03L 7/00; H03K 17/56

(52) U.S. Cl. CPC H03L 7/00; H03K 17/56

(57) ABSTRACT

A first integrated circuit and a second integrated circuit are coupled via a single-line communication line so as to form a circuit system. Multiple low times are defined in a protocol corresponding to multiple commands. The first integrated circuit fixes the electric potential of the communication line to a low level during the low time that corresponds to a command to be transmitted, so as to allow the command to be transmitted to the second integrated circuit.

### CROSS REFERENCE TO RELATED APPLICATIONS

The present invention claims priority under 35 U.S.C. § 119 to Japanese Application No.2023-173210, filed Oct. 4, 2023, the entire content of which is incorporated herein by reference.

### BACKGROUND

### 1. Technical Field

The present disclosure relates to a circuit system.

### 2. Description of the Related Art

Cellular phones, tablet terminals, laptop personal computers (PCs), desktop PCs, and game machines are each provided with a microprocessor such as a Central Processing Unit (CPU), a Graphics Processing Unit (CPU), or the like, configured to support calculation processing.

With the miniaturization of the semiconductor manufacturing process, the increase in the number of peripheral circuits to be mounted, and the demand for reduced power consumption, an electronic device configured to mount a microprocessor is divided into multiple circuit blocks and is configured to allow the power supply voltage to be controlled independently for each circuit block.

In such devices, in order to control multiple power supply systems that correspond to the multiple circuit blocks, a power supply controller circuit is employed. The power supply controller circuit will also be referred to as a Power Management Integrated Circuit (PMIC).

A power supply controller circuit is provided with a sequencer. The sequencer is required to control the turning on/off of the multiple power supply lanes in a sure manner according to a predetermined sequence.

The power supply controller circuit controls the multiple power supply lanes in units of time called slots. For example, after the sequence starts, this is capable of forming a sequence such that the first power supply lane is turned on in the third slot, the second power supply lane is turned on in the fourth slot, the third power supply lane is turned on in the sixth slot, and so on.

Let us consider a case in which a system is designed using a given PMIC. If the number of the power supply lanes to be controlled (which is also referred to as the “number of lanes” or the “number of channels”) becomes larger than the number of the power supply lanes that can be supported by the PMIC employed in the original design, such a proven PMIC cannot be employed. Instead, it is necessary to redesign the system from scratch employing a new unproven PMIC. If such a proven PMIC employed in the original design can be continuously employed, this allows the burden on the designer to be dramatically reduced.

Such a problem can occur in various kinds of integrated circuits for various kinds of usages, in addition to such a PMIC.

### BRIEF DESCRIPTION OF THE DRAWINGS

Embodiments will now be described, by way of example only, with reference to the accompanying drawings which are meant to be exemplary, not limiting, and wherein like elements are numbered alike in several Figures, in which:

FIG. 1 is a block diagram of a circuit system according to an embodiment,

FIG. 2 is a diagram for explaining a communication protocol of the circuit system shown in FIG. 1,

FIG. 3 is an operation waveform diagram of the circuit system shown in FIG. 1,

FIG. 4 is a block diagram showing an example configuration of a transceiver that corresponds to a first interface circuit and a second interface circuit; and

FIG. 5 is a block diagram of a power supply system.

### DETAILED DESCRIPTION

### Outline of Embodiments

Description will be made regarding the outline of several exemplary embodiments of the present disclosure. The outline is a simplified explanation regarding several concepts of one or multiple embodiments as a preface to the detailed description described later in order to provide a basic understanding of the embodiments. That is to say, the outline described below is by no means intended to restrict the scope of the present invention and the present disclosure. The outline is by no means a comprehensive outline of all possible embodiments. That is to say, the outline is by no means intended to identify the indispensable or essential elements of all the embodiments and is by no means intended to define the scope of a part of or all the embodiments. For convenience, in some cases, an “embodiment” as used in the present specification represents a single or multiple embodiments (examples and modifications) disclosed in the present specification.

A circuit system according to one embodiment includes a first integrated circuit, a second integrated circuit, and a single-line communication line that couples the first integrated circuit and the second integrated circuit. The first integrated circuit and the second integrated circuit are coupled via an open-drain bidirectional single-line interface using the communication line so as to allow them to communicate with each other. A plurality of low times are defined in a protocol corresponding to a plurality of commands. The first integrated circuit is configured to fix an electric potential of the communication line to a low level during the low time that corresponds to a command to be transmitted, so as to allow any one of the plurality of commands to be transmitted as a first command to the second integrated circuit.

With this arrangement, this allows the circuit system provided with the first integrated circuit to be further provided with the second integrated circuit as an additional circuit and allows the second integrated circuit to be controlled by the first integrated circuit. This provides flexible design of the circuit system.

In one embodiment, upon receiving the first command from among the plurality of commands, the second integrated circuit may fix the electric potential of the communication line to the low level so as to return an acknowledgment that corresponds to the first command to the first integrated circuit. This allows the first integrated circuit to receive information that the second integrated circuit has correctly received the first command transmitted from the first integrated circuit itself.

In one embodiment, upon receiving the first command from among the plurality of commands, the second integrated circuit may fix the electric potential of the communication line to the low level during the same time as the low time that corresponds to the first command, so as to return an acknowledgment that is different for each command from among the plurality of commands. With such an arrangement in which the low time that corresponds to a given command is defined so as to be equal to the low time that corresponds to the corresponding acknowledgment, this allows the first integrated circuit and the second integrated circuit to have a simple configuration.

In one embodiment, upon receiving no acknowledgment that corresponds to the first command, the first integrated circuit may execute error processing. This allows robust signal processing.

In one embodiment, the second integrated circuit may include a second sequencer. Also, a plurality of commands are defined corresponding to transitions of a plurality of states of the second sequencer. This allows the first integrated circuit to control the state of the second sequencer according to a command transmitted to the second integrated circuit.

In one embodiment, the low time that corresponds to a synchronization signal may be defined in the protocol. Also, after the transmission of the first command, the first integrated circuit may fix the electric potential of the communication line to the low level during the low time that corresponds to the synchronization signal, so as to allow the synchronization signal to be transmitted to the second integrated circuit. Also, the second sequencer may operate in synchronization with the synchronization signal.

In one embodiment, upon receiving the synchronization signal, the second integrated circuit may fix the electric potential of the communication line to the low level during the low time that corresponds to the synchronization signal, so as to return an acknowledgment that corresponds to the synchronization signal to the first integrated circuit. With such an arrangement in which the low time that corresponds to a given command is defined so as to be equal to the low time that corresponds to the corresponding acknowledgment, this allows the first integrated circuit and the second integrated circuit to have a simple configuration.

In one embodiment, the first integrated circuit may include a first sequencer. Also, the first sequencer may operate in synchronization with the acknowledgment that corresponds to the synchronization signal. This allows the first sequencer and the second sequencer to operate in synchronization.

In one embodiment, upon receiving no acknowledgment that corresponds to the synchronization signal transmitted from the first integrated circuit itself, the first integrated circuit may execute error processing. This allows robust signal processing.

In one embodiment, the first integrated circuit may be configured as a power supply management circuit. Also, the second integrated circuit may be configured as a power supply circuit or a power supply management circuit.

A main integrated circuit according to one embodiment allows a circuit system to be configured together with an additional component integrated circuit. The main integrated circuit includes: a first interface pin to be coupled to the additional component integrated circuit via a single-line communication line; and a first interface circuit configured in an open-drain format coupled to the first interface pin. A plurality of low times are defined in a protocol corresponding to the plurality of commands. The first interface circuit fixes an electric potential of the communication line to a low level during the low time that corresponds to a command to be transmitted, so as to allow any one of the plurality of commands to be transmitted as a first command to the additional component integrated circuit.

An additional component integrated circuit according to one embodiment allows a circuit system to be configured together with a main integrated circuit. The additional component integrated circuit includes: a second interface pin to be coupled to the main integrated circuit via a single-line communication line; and a second interface circuit configured in an open-drain format coupled to the second interface pin. A plurality of low times are defined in a protocol corresponding to the plurality of commands. The second interface circuit detects a time during which an electric potential of the communication line is fixed to a low level by the main integrated circuit, so as to allow a first command that corresponds to the detected time to be received from the main integrated circuit from among the plurality of commands.

### Embodiments

Description will be made below regarding preferred embodiments with reference to the drawings. The same or similar components, members, and processes are denoted by the same reference numerals, and redundant description thereof will be omitted as appropriate. The embodiments have been described for exemplary purposes only and are by no means intended to restrict the present disclosure and the present invention. Also, it is not necessarily essential for the present disclosure and the present invention that all the features or a combination thereof be provided as described in the embodiments.

In the present specification, a state represented by the phrase “the member A is coupled to the member B” includes a state in which the member A is indirectly coupled to the member B via another member that does not substantially affect the electric connection between them, or that does not damage the functions or effects of the connection between them, in addition to a state in which they are physically and directly coupled.

Similarly, a state represented by the phrase “the member C is provided between the member A and the member B” includes a state in which the member A is indirectly coupled to the member C, or the member B is indirectly coupled to the member C via another member that does not substantially affect the electric connection between them, or that does not damage the functions or effects of the connection between them, in addition to a state in which they are directly coupled.

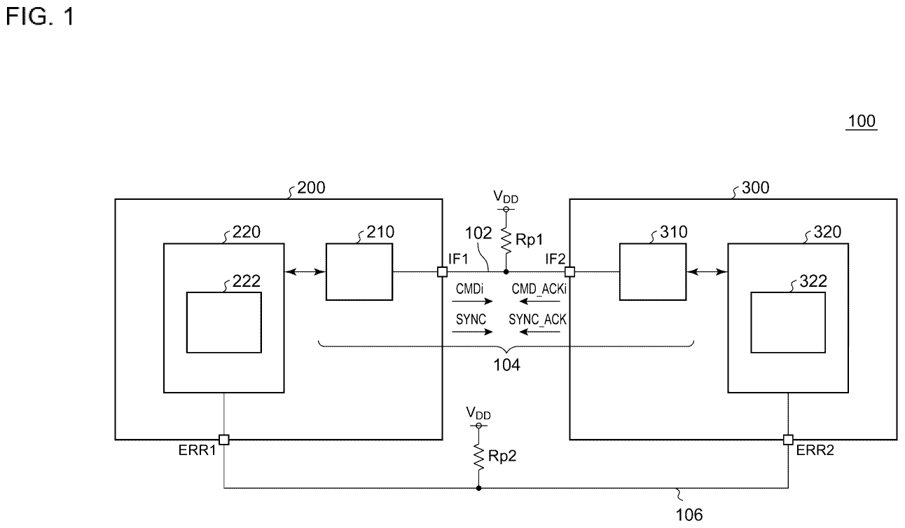

FIG. 1 is a block diagram of a circuit system 100 according to an embodiment. The circuit system 100 includes a first integrated circuit 200 and a second integrated circuit 300. The first integrated circuit 200 and the second integrated circuit 300 are designed to have a master-slave relationship. The first integrated circuit 200 is configured as a main IC. The second integrated circuit 200 is configured as an additional component accompanying the main IC. The second integrated circuit 300 operates under the control of the first integrated circuit 200.

The first integrated circuit 200 includes a first function block 220. The first function block 220 is configured to execute the main processing of the first integrated circuit 200. The functions and the configuration of the first function block 220 are not restricted in particular.

Similarly, the second integrated circuit 300 includes a second function block 320. The second function block 320 is configured to execute the main processing of the second integrated circuit 300. The functions and the configuration of the second function block 320 are not restricted in particular.

A first interface pin IF1 of the first integrated circuit 200 is coupled to a second interface pin IF2 of the second integrated circuit 300 via a communication line 102 configured as a single line. The first integrated circuit 200 and the second integrated circuit 300 are coupled so as to allow them to communicate with each other via an open-drain bidirectional single-line serial interface 104 employing the communication line 102. The communication line 102 is pulled up to a power supply line VDD via a pull-up resistor Rp1.

The first integrated circuit 200 and the second integrated circuit 300 are provided with a first interface circuit 210 and a second interface circuit 310 that form the serial interface 104.

The first function block 220 generates a command for controlling the second function block 320 and transmits the command to the second function block 320 via the serial interface 104. Specifically, the first integrated circuit 200 is capable of transmitting a desired one selected from among a plurality of n (n≥2) commands CMD1 through CMDn (which will also be referred to as a “first command”) to the second integrated circuit 300. If the number n of the commands that can be transmitted from the first integrated circuit 200 to the second integrated circuit 300 is three or more, such an arrangement is capable of supporting advanced control. The multiple low times T_{CMD1} through T_{CMDn} are defined in a protocol corresponding to the multiple commands CMD1 through CMDn. By fixing the communication line 102 to the low level (0 V) during the low time T_{CMDi} that corresponds to the transmission command CMDi(i=1, . . . , n), the first integrated circuit 200 is capable of transmitting one from among the multiple commands CMD1 through CMDn as the transmission command CMDi to the second integrated circuit 300.

The first interface circuit 210 and the second interface circuit 310 are each configured as a transceiver that is capable of transmitting and receiving a signal in a bidirectional manner. When a desired one CMDi selected from among the multiple commands CMD1 through CMDn is transmitted as a transmission command from the first interface circuit 210 to the second interface circuit 310, the first interface circuit 210 fixes the electric potential V_{COM} of the communication line 102, i.e., the electric potential at the first interface pin IF1, to the low level during the low time T_{CMDi}.

The second interface circuit 310 monitors the electric potential at the second interface pin IF2, i.e., the electric potential V_{COM} of the communication line 102. The second interface circuit 310 detects the time T_{LOW} during which the electric potential at the second interface pin IF2 is fixed to the low level. The second interface circuit 310 judges which one from among the low times T_{CMD1} through T_{CMDn} that correspond to the multiple commands matches the detected time T_{LOW} . If the detected time is T_{CMDi}, the second interface circuit 310 receives the i-th command CMDi as the transmission command.

The second interface circuit 310 is configured to return an acknowledgment CMD_ACK to the first interface circuit 210 when the second interface circuit 310 receives a transmission command CMD from the first interface circuit 210.

Multiple acknowledgments CMD_ACK1 through CMD_ACKn are preferably defined corresponding to the multiple commands CMD1 through CMDn. That is to say, upon receiving the transmission command CMDi, the second interface circuit 310 returns the acknowledgment CMD_ACKi. With this, if the first interface circuit 210 receives the corresponding acknowledgment CMD_ACKi after it transmits the transmission command CMDi, the first interface circuit 210 is capable of receiving information that the transmission command has been transmitted correctly.

Conversely, if the first interface circuit 210 receives the acknowledgment CMD_ACKj (j≠i) that does not correspond to the transmission command CMDi after it transmits the transmission command CMDi, the first interface circuit 210 is capable of receiving information that the transmission command has not been transmitted correctly (transmission error).

When a transmission error occurs, the first integrated circuit 200 may execute predetermined error processing. An error pin ERR1 of the first integrated circuit 200 and an error pin ERR2 of the second integrated circuit 300 are coupled via an error signal line 106 that differs from the communication line 102. The signal line 106 is pulled up to the power supply line via a pull-up resistor Rp2. When a transmission error occurs, the first function block 220 fixes the electric potential of the signal line 106 to the low level so as to notify the second function block 320 of the occurrence of the transmission error. The second function block 320 executes error processing in response to a notice of the occurrence of the transmission error.

The first function block 220 may be provided with a first sequencer 222. Similarly, the second function block 320 may be provided with a second sequencer 322 that is to operate in conjunction with the first sequencer 222. In this case, the multiple commands CMD1 through CMDn may include control commands for the second sequencer 322.

The overall circuit system 100 may support n sequence controls SEQ1 through SEQn. The commands CMD1 through CMDn are defined corresponding to the sequence controls SEQ1 through SEQn.

When the first integrated circuit 200 detects an event that becomes a trigger of the i-th (i=1, 2, . . . , n) sequence control SEQi, the first interface circuit 210 transmits the i-th command CMDi as the transmission command to the second interface circuit 310. Furthermore, the first interface circuit 210 executes a main-side process P_{MAINi} that corresponds to the i-th sequence control SEQi. When the second interface circuit 310 receives the transmission command CMDi, the second function block 320 executes additional component-side processing P_{AUXi} that corresponds to the i-th sequence control SEQi according to the transmission command CMDi as a trigger.

Furthermore, the first interface circuit 210 is configured to be capable of transmitting a synchronization signal SYNC to the second interface circuit 310 in order to allow the first sequencer 222 and the second sequencer 322 to execute the processes P_{MAINi} and P_{AUXi} that correspond to the sequence control SEQi in conjunction.

In the protocol of the serial interface 104, the low time T_{SYNC} that corresponds to the synchronization signal SYNC is defined. The first interface circuit 210 of the first integrated circuit 200 fixes the communication line 102 to the low level during the low time T_{SYNC} so as to transmit the synchronization signal SYNC to the second integrated circuit 300.

The second interface circuit 310 detects the time T_{LOW} during which the electric potential at the second interface pin IF2 is fixed to the low level. In a case in which the detected time T_{LOW} matches the low time T_{SYNC} that corresponds to the synchronization signal SYNC, the second interface circuit 310 receives the synchronization signal SYNC.

After the first integrated circuit 200 transmits the transmission command CMDi, the first integrated circuit 200 may repeat the synchronization signal SYNC multiple times, so as to transmit it to the second integrated circuit 300 at predetermined time intervals (which are referred to as “time slots”). This allows the first sequencer 222 on the first integrated circuit 200 side and the second sequencer 322 on the second integrated circuit 300 side to operate in synchronization with respect to the time slots.

The second interface circuit 310 of the second integrated circuit 300 fixes the communication line 102 to the low level during the low time T_{SYNC} that corresponds to the synchronization signal SYNC so as to return the acknowledgment SYNC_ACK that corresponds to the synchronization signal SYNC to the first integrated circuit 200 every time the second interface circuit 310 receives the synchronization signal SYNC.

The second sequencer 322 may be configured to operate in synchronization with reception of the synchronization signal SYNC by the second interface circuit 310. The first sequencer 222 may be configured to operate in synchronization with reception of the acknowledgment SYNC_ACK by the first interface circuit 210.

The second sequencer 322 may be configured to operate in synchronization with the completion of transmission of the acknowledgment SYNC_ACK from the second interface circuit 310. The first sequencer 222 may be configured to operate in synchronization with reception of the acknowledgment SYNC_ACK by the first interface circuit 210. With this arrangement in which the first sequencer 222 and the second sequencer 322 operate with the same acknowledgment as a reference, this provides the operation with high synchronization.

It should be noted that the second sequencer 322 may be configured to operate in synchronization with reception of the synchronization signal SYNC by the second interface circuit 310. The first sequencer 222 may be configured to operate in synchronization with transmission of the synchronization signal SYNC by the first interface circuit 210.

When the first integrated circuit 200 has received no acknowledgment SYNC_ACK that corresponds to the synchronization signal SYNC transmitted by the first integrated circuit 200 itself, the first integrated circuit 200 judges that a transmission error has occurred and executes error processing. When a transmission error occurs, the first function block 220 fixes the electric potential V_{COM} of the signal line 106 to the low level, so as to notify the second function block 320 of the occurrence of the transmission error. The second function block 320 executes error processing in response to the notice of the transmission error.

The above is the configuration of the circuit system 100. Next, description will be made regarding the communication protocol of the serial interface 104.

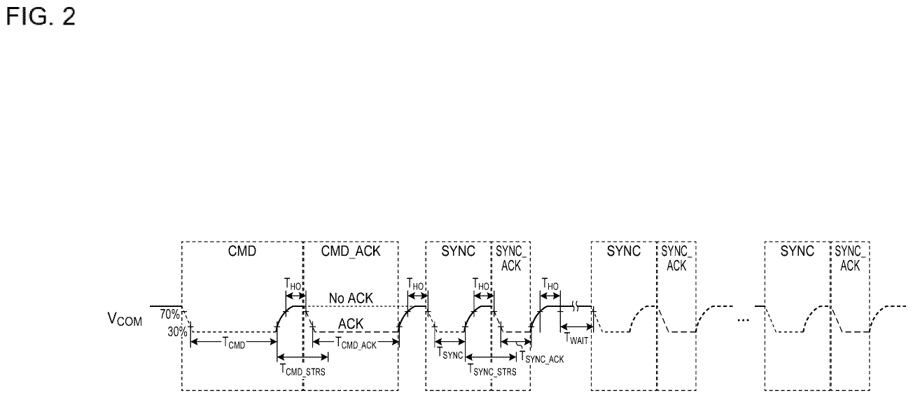

FIG. 2 is a diagram for explaining the communication protocol of the circuit system 100 shown in FIG. 1. FIG. 2 shows the electric potential V_{COM} of the communication line 102. The electric potential V_{COM} of the communication line 102 changes based on the following times defined in the protocol.
T_{CMDi}: Low time that corresponds to a command.
T_{HD}: Handoff time.
T_{CMD_ACK}: Low time that corresponds to an acknowledgment of a command.
T_{CMD_STRB}: Strobe time of a command.
T_{SYNC}: Low time that corresponds to the synchronization signal.
T_{SYNC_ ACK}: Low time that corresponds to the acknowledgment of a synchronization signal.
T_{WAIT}: Waiting time.

The waiting time T_{WAIT} represents a parameter that defines the time interval of the synchronization signal SYNC. Accordingly, the waiting time T_{WAIT} defines the time length of one slot.

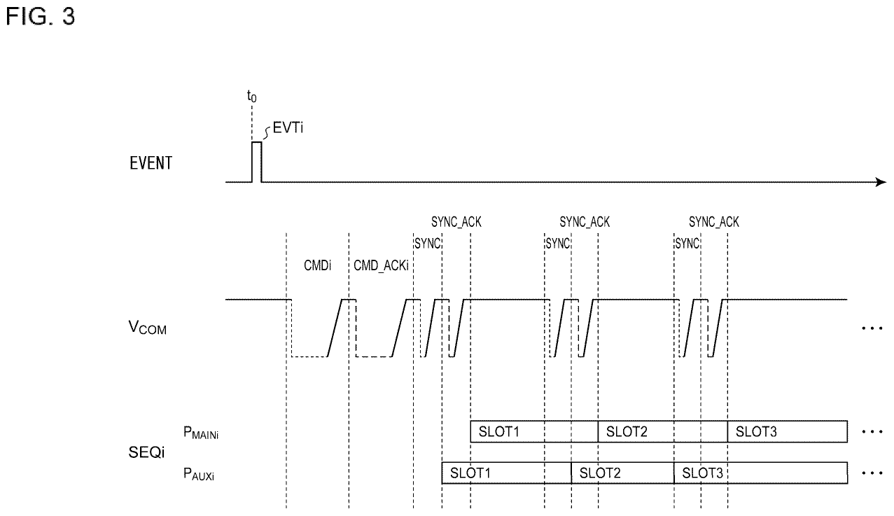

FIG. 3 is an operation waveform diagram of the circuit system 100 shown in FIG. 1. At the time point t0, an event EVTi occurs as a trigger of the sequence control SEQi. Upon detecting the event EVTi, the first integrated circuit 200 transmits the corresponding command CMDi as the transmission command to the second integrated circuit 300. The second integrated circuit 300 returns the acknowledgment CMD_ACKi that corresponds to the transmission command CMDi to the first integrated circuit 200. With this, the first integrated circuit 200 and the second integrated circuit 300 become in a state in which they are able to execute the processes P_{MAINi} and P_{AUXi} associated with the sequence control SEQi. The processes P_{MAINi} and P_{AUXi} each include multiple steps and are controlled in units of time that are called “slots”.

Upon receiving the acknowledgment CMD_ACKi that corresponds to the transmission command CMDi, the first integrated circuit 200 transmits the synchronization signal SYNC to the second integrated circuit 300. Subsequently, the second integrated circuit 300 returns the acknowledgment SYNC_ACK that corresponds to the synchronization signal SYNC. For example, the slot of the second sequencer 322 on the second integrated circuit 300 side is incremented by the reception of the synchronization signal SYNC. The slot of the first sequencer 222 on the first integrated circuit 200 side is incremented by reception of the acknowledgment SYNC_ACK.

The above is the operation of the circuit system 100. With the circuit system 100, this allows the first integrated circuit 200 to control the state of the second integrated circuit 300 via communication using the communication line 102. Specifically, this allows the first integrated circuit 200 to transmit different commands to the second integrated circuit 300. Furthermore, with such an arrangement in which the first integrated circuit 200 is configured to transmit the synchronization signal SYNC, this allows signal processing to be synchronized between the first integrated circuit 200 and the second integrated circuit 300.

Description will be made assuming that a system designed by a designer includes only the first integrated circuit 200. Furthermore, description will be made assuming that, after the system is designed, a change occurs in the system, leading to the addition of the second integrated circuit 300. In this case, the first integrated circuit 200 and the second integrated circuit 300 are coupled via the communication line 102. This allows the first integrated circuit 200 to control the second integrated circuit 300. That is to say, this provides the first integrated circuit 200 and the second integrated circuit 300 with improved scalability for flexible design of the circuit system.

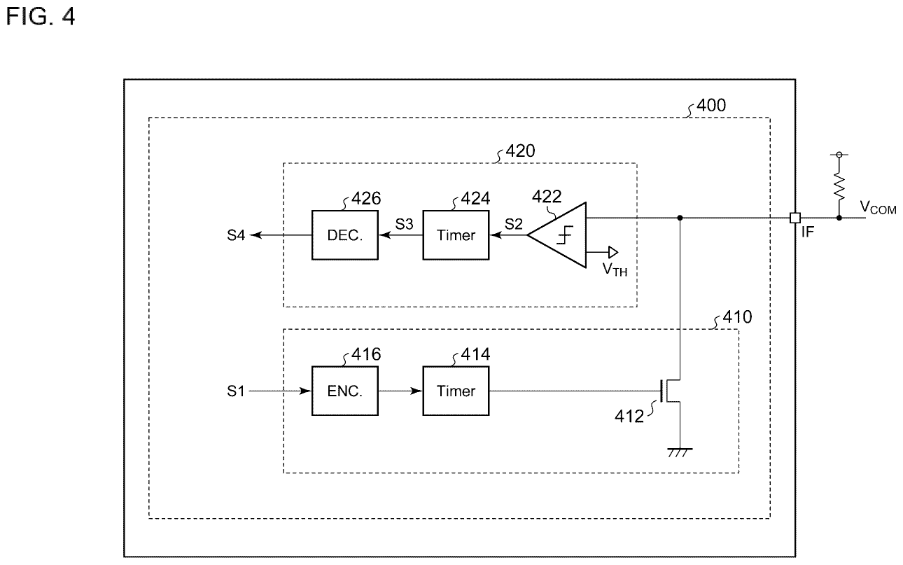

FIG. 4 is a block diagram showing an example configuration of a transceiver 400 that corresponds to the first interface circuit 210 and the second interface circuit 310.

The transceiver 400 includes a transmitter 410 and a receiver 420. The transmitter 410 includes a transistor 412 with a drain coupled to the interface pin IF, a timer circuit 414, and an encoder 416. The encoder 416 receives information S1 to be transmitted to the transceiver of a communication partner. In a case in which the transceiver 400 is configured as the first interface circuit 210, the information S1 specifies the command CMDi or the synchronization signal SYNC. In a case in which the transceiver 400 is configured as the second interface circuit 310, the information S1 specifies the acknowledgment CMD_AKCi or SYNC_ACK.

The timer circuit 414 turns on the transistor 412 during the time that corresponds to the information S1 received by the encoder 416. For example, when the information S1 indicates the command CMDi, the timer circuit 414 turns on the transistor 412 during the time T_{CMDi}.

The receiver 420 includes a comparator 422, a timer circuit 424, and a decoder 426. The comparator 422 compares the electric potential V_{COM} at the interface pin IF with the threshold voltage V_{TH}. When the electric potential V_{COM} is the low level, the comparator 422 outputs a comparison signal S2 with a predetermined level. The timer circuit 424 receives the comparison signal S2 from the comparator 422. The timer circuit 424 outputs a signal S3 that indicates a time T_{LOW} in which the comparison signal S2 is the predetermined level, i.e., the time T_{LOW} in which the electric potential V_{COM} is the low level. The decoder 426 receives the signal S3, and outputs information S4 that corresponds to the time T_{LOW}.

It should be noted that the configuration of the transceiver 400 is not restricted to an arrangement shown in FIG. 4. Also, known techniques or techniques that will become available in the future may be employed.

Next, description will be made regarding the usage of the circuit system 100. The circuit system 100 is configured as a power supply system. The first integrated circuit 200 and the second integrated circuit 300 may each be configured as a power supply management IC (PMIC). It should be noted that the second integrated circuit 300 may be configured as a power supply IC with only a single channel.

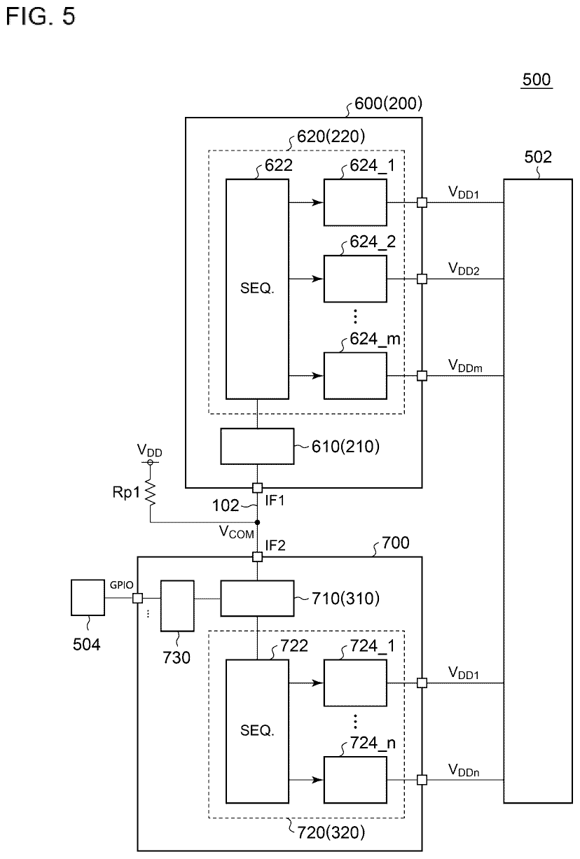

FIG. 5 is a block diagram of a power supply system 500. The power supply system 500 includes a load 502, a first PMIC 600, and a second PMIC 700. The first PMIC 600 corresponds to the first integrated circuit 200 described above. The second PMIC 700 corresponds to the second integrated circuit 300 described above. The first PMIC 600 and the second PMIC 700 are each capable of supplying multiple power supply voltages V_{DD} to the load 502. The load 502 may be configured as a single IC such as a microcontroller, System on Chip (SOC), or the like provided with multiple power supply terminals. Also, the load 502 may be configured as a set of multiple ICs.

The first PMIC 600 includes a first interface circuit 610 and a multi-channel (m-channel) power supply circuit 620. The first interface circuit 610 corresponds to the first interface circuit 210. The power supply circuit 620 corresponds to the first function block 220. The power supply circuit 620 includes a first sequencer 622 and multiple power supply units 624_1 through 624_m. The first sequencer 622 corresponds to the first sequencer 222. The power supply units 624_1 through 624_m generate power supply voltages V_{DD1} through V_{DDm}. The power supply units 624_1 through 624_m may be configured as switching power supplies such as buck converters, boost converters, or the like, or linear regulators. It should be noted that FIG. 5 shows no peripheral circuit components such as capacitors, inductors, etc.

The second PMIC 700 includes a second interface circuit 710 and a multi-channel (n-channel) power supply circuit 720. The second interface circuit 710 corresponds to the second interface circuit 310. The power supply circuit 720 corresponds to the second function block 320. The power supply circuit 720 includes a second sequencer 722 and multiple power supply units 724_1 through 724_n. The second sequencer 722 corresponds to the second sequencer 322. The power supply units 724_1 through 724_n generate power supply voltages V_{DD1} through V_{DDn}. The power supply units 724_1 through 724_n may be configured as switching power supplies such as buck converters, boost converters, or the like, or linear regulators.

The load 502 is switchable between multiple states. The power supply system 500 switches each of the multiple power supply voltages V_{DD} to be supplied to the load 502 between off and on according to the state of the load 502. There are various kinds and names of the switchable states of the load 502. The kinds and names of the states of the load 502 are not restricted in particular.

In the power supply system 500, the first PMIC 600 transmits a command to the second PMIC 700. This allows the states of the multiple power supply units 724_1 through 724_n on the second PMIC 700 side to be controlled in synchronization with the states of the power supply units 624_1 through 624_m on the first PMIC 600 side.

The second PMIC 700 is further provided with a General Purpose Input/Output (GPIO) circuit 730. The GPIO circuit 730 includes at least one output terminal GPIO. The multiple commands to be transmitted from the first interface circuit 610 to the second interface circuit 710 may include a command for controlling the state of each output terminal GPIO of the GPIO circuit 730. Similarly, the first PMIC 600 may include a GPIO circuit (not shown). Also, the first sequencer 622 may be configured to be capable of controlling the state of the GPIO circuit on the first PMIC 600 side.

The GPIO circuit 730 allows an additional component IC 504 to be further coupled to the output terminal GPIO. The additional component IC 504 may be configured as an IC provided with a control terminal such as an enable terminal EN or the like for receiving a binary signal switchable between high and low. This allows the on/off state of the additional component IC 504 to be controlled according to the state of the output terminal GPIO of the GPIO circuit 730. With this, by transmitting a command from the first PMIC 600 to the second PMIC 700 in the power supply system 500, in addition to the states of the power supply units 724_1 through 724_n on the second PMIC 700 side, this allows the state of the additional component IC 504 to be controlled in synchronization with the states of the power supply units 624_1 through 624_m on the first PMIC 600 side.

As the additional component IC 504, an IC having a desired function may be coupled. For example, the additional component 504 may be configured as a controller circuit for a linear regulator or a DC/DC converter. This allows the total number of channels of the power supply system 500 to be further increased. Furthermore, this allows the power supply circuit configured as the additional component IC 504 to be controlled in synchronization with other power supply units.

The embodiments have been described for exemplary purposes only. Rather, it can be readily conceived by those skilled in this art that various modifications may be made by making various combinations of the aforementioned components or processes, which are also encompassed in the present disclosure.

The first integrated circuit 200 and the second integrated circuit 300 are coupled via an open-drain bidirectional single-line serial interface 104 using the communication line 102 so as to allow them to communicate with each other. In the bidirectional single-line serial interface 104, the handoff time T_{H} is defined to be longer than the transition time from the low level L to the high level H after the transmission of the command CMDi and the acknowledgment CMD_ACKi. The bidirectional single-line serial interface 104 may include a conversion circuit configured to temporarily switch from the open-drain format to the push-pull format, or a switching circuit configured to switch between push-pull formats. Such a conversion circuit or a switching circuit allows the circuit system 100 to provide a reduced handoff time even if the pull-up resistor has a large resistance. The conversion circuit or the switching circuit allows the circuit system 100 to provide high-speed communication while suppressing current consumption in communication.

### Notes

An aspect of the technique disclosed in the present specification can be understood as follows.

### Item 1

A circuit system comprising:
a first integrated circuit;
a second integrated circuit; and
a single-line communication line that couples the first integrated circuit and the second integrated circuit,
wherein the first integrated circuit and the second integrated circuit are coupled via an open-drain bidirectional single-line interface using the communication line so as to allow them to communicate with each other,
wherein a plurality of low times are defined in a protocol corresponding to a plurality of commands respectively,
and wherein the first integrated circuit is structured to fix an electric potential of the communication line to a low level during the low time that corresponds to a command to be transmitted, so as to allow any one of the plurality of commands to be transmitted as a first command to the second integrated circuit.

### Item 2

The circuit system according to item 1, wherein, upon receiving the first command from among the plurality of commands, the second integrated circuit fixes the electric potential of the communication line to the low level so as to return an acknowledgment that corresponds to the first command to the first integrated circuit.

### Item 3

The circuit system according to item 2, wherein, upon receiving the first command from among the plurality of commands, the second integrated circuit fixes the electric potential of the communication line to the low level during the same time as the low time that corresponds to the first command, so as to return an acknowledgment that is different for each command from among the plurality of commands.

### Item 4

The circuit system according to item 3, wherein, upon receiving no acknowledgment that corresponds to the first command, the first integrated circuit executes error processing.

### Item 5

The circuit system according to any one of items 1 through 4, wherein the second integrated circuit comprises a second sequencer,
and wherein the plurality of commands are defined corresponding to transitions of a plurality of states of the second sequencer.

### Item 6

The circuit system according to item 5, wherein the low time that corresponds to a synchronization signal is defined in the protocol,
wherein, after the transmission of the first command, the first integrated circuit fixes the electric potential of the communication line to the low level during the low time that corresponds to the synchronization signal, so as to allow the synchronization signal to be transmitted to the second integrated circuit,
and wherein the second sequencer operates in synchronization with the synchronization signal.

### Item 7

The circuit system according to item 6, wherein, upon receiving the synchronization signal, the second integrated circuit fixes the electric potential of the communication line to the low level during the low time that corresponds to the synchronization signal, so as to return an acknowledgment that corresponds to the synchronization signal to the first integrated circuit.

### Item 8

The circuit system according to item 7, wherein the first integrated circuit comprises a first sequencer,
and wherein the first sequencer operates in synchronization with the acknowledgment that corresponds to the synchronization signal.

### Item 9

The circuit system according to item 7 or 8, wherein, upon receiving no acknowledgment that corresponds to the synchronization signal transmitted from the first integrated circuit itself, the first integrated circuit executes error processing.

### Item 10

The circuit system according to any one of items 1 through 9, wherein the first integrated circuit is structured as a power supply management circuit, and wherein the second integrated circuit is structured as a power supply circuit or a power supply management circuit.

### Item 11

A main integrated circuit that allows a circuit system to be structured together with an additional component integrated circuit, the main integrated circuit comprising:
a first interface pin to be coupled to the additional component integrated circuit via a single-line communication line; and
a first interface circuit structured in an open-drain format coupled to the first interface pin,
wherein a plurality of low times to be used as a plurality of commands are defined in a protocol corresponding to the plurality of commands,
and wherein the first interface circuit fixes an electric potential of the communication line to a low level during the low time that corresponds to a command to be transmitted, so as to allow any one of the plurality of commands to be transmitted as a first command to the additional component integrated circuit.

### Item 12

An additional component integrated circuit that allows a circuit system to be structured together with a main integrated circuit, the additional component integrated circuit comprising:
a second interface pin to be coupled to the main integrated circuit via a single-line communication line; and
a second interface circuit structured in an open-drain format coupled to the second interface pin,
wherein a plurality of low times to be used as a plurality of commands are defined in a protocol corresponding to the plurality of commands,
and wherein the second interface circuit detects a time during which an electric potential of the communication line is fixed to a low level by the main integrated circuit, so as to allow a first command that corresponds to the detected time to be received from the main integrated circuit from among the plurality of commands.

What is claimed is:

1. A circuit system comprising:
a first integrated circuit;
a second integrated circuit; and
a single-line communication line that couples the first integrated circuit and the second integrated circuit,
wherein the first integrated circuit and the second integrated circuit are coupled via an open-drain bidirectional single-line interface using the communication line so as to allow them to communicate with each other,
wherein a plurality of low times are defined in a protocol corresponding to a plurality of commands respectively,
and wherein the first integrated circuit is structured to fix an electric potential of the communication line to a low level during the low time that corresponds to a command to be transmitted, so as to allow any one of the plurality of commands to be transmitted as a first command to the second integrated circuit.

2. The circuit system according to claim 1, wherein, upon receiving the first command from among the plurality of commands, the second integrated circuit fixes the electric potential of the communication line to the low level so as to return an acknowledgment that corresponds to the first command to the first integrated circuit.

3. The circuit system according to claim 2, wherein, upon receiving the first command from among the plurality of commands, the second integrated circuit fixes the electric potential of the communication line to the low level during the same time as the low time that corresponds to the first command, so as to return an acknowledgment that is different for each command from among the plurality of commands.

4. The circuit system according to claim 3, wherein, upon receiving no acknowledgment that corresponds to the first command, the first integrated circuit executes error processing.

5. The circuit system according to claim 1, wherein the second integrated circuit comprises a second sequencer,
and wherein the plurality of commands is defined corresponding to transitions of a plurality of states of the second sequencer.

6. The circuit system according to claim 5, wherein the low time that corresponds to a synchronization signal is defined in the protocol,
wherein, after the transmission of the first command, the first integrated circuit fixes the electric potential of the communication line to the low level during the low time that corresponds to the synchronization signal, so as to allow the synchronization signal to be transmitted to the second integrated circuit,
and wherein the second sequencer operates in synchronization with the synchronization signal.

7. The circuit system according to claim 6, wherein, upon receiving the synchronization signal, the second integrated circuit fixes the electric potential of the communication line to the low level during the low time that corresponds to the synchronization signal, so as to return an acknowledgment that corresponds to the synchronization signal to the first integrated circuit.

8. The circuit system according to claim 7, wherein the first integrated circuit comprises a first sequencer,
and wherein the first sequencer operates in synchronization with the acknowledgment that corresponds to the synchronization signal.

9. The circuit system according to claim 7, wherein, upon receiving no acknowledgment that corresponds to the synchronization signal transmitted from the first integrated circuit itself, the first integrated circuit executes error processing.

10. The circuit system according to claim 1, wherein the first integrated circuit is structured as a power supply management circuit,
and wherein the second integrated circuit is structured as a power supply circuit or a power supply management circuit.

11. A main integrated circuit that allows a circuit system to be structured together with an additional component integrated circuit, the main integrated circuit comprising:
a first interface pin to be coupled to the additional component integrated circuit via a single-line communication line; and
a first interface circuit structured in an open-drain format coupled to the first interface pin,
wherein a plurality of low times to be used as a plurality of commands are defined in a protocol corresponding to the plurality of commands,
and wherein the first interface circuit fixes an electric potential of the communication line to a low level during the low time that corresponds to a command to be transmitted, so as to allow any one of the plurality of commands to be transmitted as a first command to the additional component integrated circuit.

12. An additional component integrated circuit that allows a circuit system to be structured together with a main integrated circuit, the additional component integrated circuit comprising:
a second interface pin to be coupled to the main integrated circuit via a single-line communication line; and
a second interface circuit structured in an open-drain format coupled to the second interface pin,
wherein a plurality of low times to be used as a plurality of commands are defined in a protocol corresponding to the plurality of commands,
and wherein the second interface circuit detects a time during which an electric potential of the communication line is fixed to a low level by the main integrated circuit, so as to allow a first command that corresponds to the detected time to be received from the main integrated circuit from among the plurality of commands.
